(19) United States
(12) Patent Application Publication
(10) Pub. No.: US 2026/0293156 A1
(43) Pub. Date: Sep. 24, 2026

(54) STORAGE DEVICE

(71) Applicant: Kioxia Corporation, Tokyo (JP)

(72) Inventors: Tian LI, Yokohama Kanagawa (JP); Masatoshi YOSHIKAWA, Setagaya Tokyo (JP)

(21) Appl. No.: 19/325,326

(22) Filed: Sep. 10, 2025

(30) Foreign Application Priority Data
Mar. 19, 2025 (JP) 2025-045718

(51) Int. Cl. H10B 61/00; H10N 50/10; H10N 50/85

(52) U.S. Cl. CPC H10B 61/20; H10N 50/10; H10N 50/85

(57) ABSTRACT

A storage device is provided. According to embodiments, a first material extends in a first direction, is located in a second direction with respect to a first conductor, and is electrically connected to the first conductor, wherein the second direction intersects the first direction. A second conductor is electrically connected to the first material. A second material is located in the second direction with respect to the first material and is in contact with the first material. A third material is located in the second direction with respect to the second material and is in contact with the second material. A magnetoresistance effect element is located in the second direction with respect to the third material and is connected to the third material. A third conductor is located in the second direction with respect to the magnetoresistance effect element.

### CROSS-REFERENCE TO RELATED APPLICATION

This application is based upon and claims the benefit of priority from Japanese Patent Application No. 2025-045718, filed Mar. 19, 2025, the entire contents of which are incorporated herein by reference.

### FIELD

Embodiments described herein relate generally to a storage device.

### BACKGROUND

Storage devices for storing data using magnetization are known.

### BRIEF DESCRIPTION OF THE DRAWINGS

FIG. 1 shows functional blocks of a storage device of a first embodiment.

FIG. 2 shows components of a memory cell array of the storage device of the first embodiment and the connections of the components.

FIG. 3 shows a layout along an X-Y plane of some components of a part of the memory cell array of the storage device of the first embodiment.

FIG. 4 shows a layout along the X-Y plane of some components of another part of the memory cell array of the storage device of the first embodiment.

FIG. 5 shows the structure of a part of the storage device of the first embodiment.

FIG. 6 shows an MTJ element of the storage device of the first embodiment and its surrounding structure.

FIG. 7 shows an MTJ element of a storage device in a modification of the first embodiment and its surrounding structure.

FIG. 8 shows an MTJ element of a storage device in another modification of the first embodiment, and its surrounding structure.

FIG. 9 shows an MTJ element of a storage device in another modification of the first embodiment, and its surrounding structure.

### DETAILED DESCRIPTION

A storage device having stable magnetization is provided.

In general, according to embodiments, a storage device includes a first conductor, a second conductor, a third conductor, a first material, a second material, a third material, and a magnetoresistance effect element. The first material extends in a first direction, is located in a second direction with respect to the first conductor, and is electrically connected to the first conductor, wherein the second direction intersects the first direction. The second conductor is electrically connected to the first material. The second material is located in the second direction with respect to the first material, is in contact with the first material, and contains one or more of titanium, magnesium, and aluminum. The third material is located in the second direction with respect to the second material, is in contact with the second material, and contains (1) a metal selected from tungsten, tantalum, molybdenum, hafnium, and rare earth metals, (2) a material comprising titanium and oxygen, (3) a material comprising titanium and nitrogen, (4) a material comprising magnesium and oxygen, (5) a material comprising magnesium and nitrogen, (6) a material comprising aluminum and oxygen, (7) a material comprising aluminum and nitrogen, (8) a material comprising nickel and oxygen, or (9) a material comprising nickel and nitrogen. The magnetoresistance effect element is located in the second direction with respect to the third material and is connected to the third material. The third conductor is located in the second direction with respect to the magnetoresistance effect element. The magnetoresistance effect element is electrically connected between the third conductor and the third material. The second material and the third material have a lower value for a magnetic property than the first material has.

Embodiments will be described below with reference to the drawings. In an embodiment or in different embodiments, a plurality of components having substantially the same functions and configurations may have additional numbers or letters added to the ends of reference signs in order to distinguish them from one another.

The drawings are schematically illustrated, and the illustrated relationships between thicknesses and planar dimensions, the thickness ratios of respective layers, etc. may differ from the actual ones. Furthermore, the drawings may include parts illustrated with different dimensional relationships, arrangements, and/or ratios than the actual ones.

In the present specification and claims, a first element being “connected” to another second element includes the first element being connected to the second element directly or via an element that is always or selectively conductive.

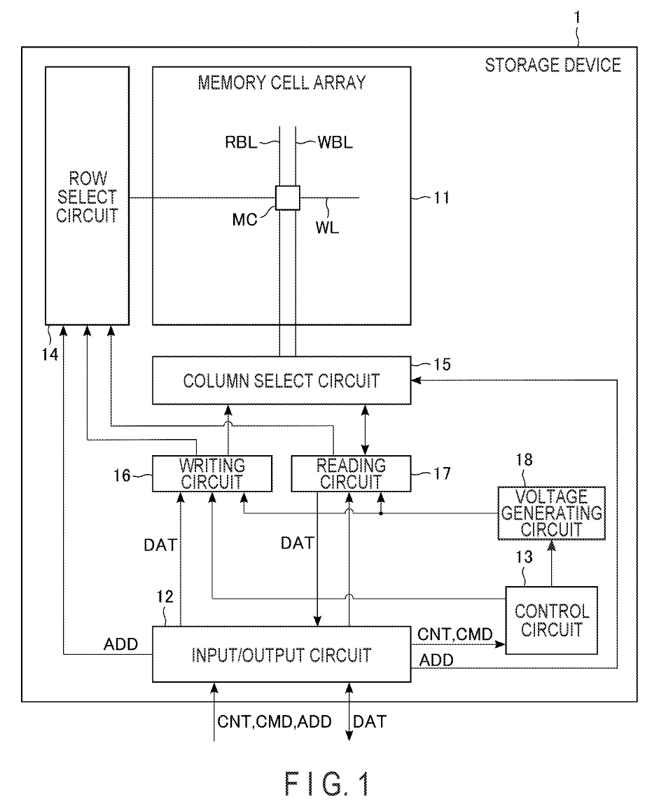

FIG. 1 shows functional blocks of a storage device 1 according to a first embodiment. The storage device 1 is a magnetic storage device for storing data using a stacked body of a magnetic material that exhibits dynamically variable resistance. As shown in FIG. 1, the storage device 1 includes a memory cell array 11, an input/output circuit 12, a control circuit 13, a row select circuit 14, a column select circuit 15, a writing circuit 16, a reading circuit 17, and a voltage generating circuit 18.

The memory cell array 11 is a functional block for storing data. The memory cell array 11 includes a plurality of memory cells MC. The memory cells MC can store data in a non-volatile manner. Each memory cell MC is associated with a pair of a row and a column. A plurality of memory cells MC associated with the same row are connected to one word line WL. A plurality of memory cells MC associated with the same column are connected to one reading bit line RBL and one writing bit line WBL.

The input/output circuit 12 is a circuit for inputting and outputting data and signals. The input/output circuit 12 receives a control signal CNT, a command CMD, address information ADD, and data DAT from the outside of the storage device 1. The input/output circuit 12 outputs data DAT. In the case of data writing into the storage device 1, the data DAT is writing data. In the case of data reading from the storage device 1, the data DAT is reading data.

The voltage generating circuit 18 is a circuit for generating voltages having various magnitudes from a voltage received from the outside of the storage device 1. The voltage generating circuit 18 outputs a voltage to be used for data reading. The voltage generating circuit 18 also outputs a voltage to be used for data writing.

The writing circuit 16 is a circuit for controlling writing of data into the memory cells MC. The writing circuit 16 receives writing data DAT from the input/output circuit 12, and receives a voltage for data writing from the voltage generating circuit 18. The writing circuit 16 outputs a voltage and a current to be used for data writing based on the control of the control circuit 13 and the writing data DAT.

The reading circuit 17 is a circuit for controlling reading of data from the memory cells MC. The reading circuit 17 receives a voltage for data reading from the voltage generating circuit 18. The reading circuit 17 determines data stored in the memory cell MC using the voltage to be used for data reading based on the control of the control circuit 13. The determined data is supplied to the input/output circuit 12 as reading data DAT. The reading circuit 17 includes a sense amplifier.

The row select circuit 14 is a circuit for selecting a row of memory cells MC. The row select circuit 14 receives address information ADD from the input/output circuit 12. The row select circuit 14 receives a voltage for data writing from the writing circuit 16. The row select circuit 14 receives a voltage for data reading from the reading circuit 17. During data writing, the row select circuit 14 uses the voltage for data writing to cause one or more word lines WL associated with a row specified by the received address information ADD to fall into a selected state. During data reading, the row select circuit 14 uses the voltage for data reading to cause a word line WL associated with a row specified by the received address information ADD to fall into a selected state.

The column select circuit 15 is a circuit for selecting a column of memory cells MC. The column select circuit 15 receives address information ADD from the input/output circuit 12. The column select circuit 15 receives a voltage for data writing from the writing circuit 16. The column select circuit 15 receives a voltage for data reading from the reading circuit 17. During data writing, the column select circuit 15 uses the voltage for data writing to cause a writing bit line WBL associated with a column specified by the received address information ADD to fall into a selected state. During data reading, the column select circuit 15 uses the voltage for data reading to cause one reading bit line RBL associated with a column specified by the received address information ADD to fall into a selected state.

The control circuit 13 is a circuit for controlling the operation of the storage device 1. The control circuit 13 receives a control signal CNT and a command CMD from the input/output circuit 12. The control circuit 13 controls the writing circuit 16 and the reading circuit 17 based on the control indicated by the control signal CNT and the command CMD. Specifically, the control circuit 13 controls the writing circuit 16 to supply the voltage received by the writing circuit 16 from the voltage generating circuit 18, to the row select circuit 14 and the column select circuit 15 during writing of data into the memory cell MC. The control circuit 13 controls the reading circuit 17 to supply the voltage received by the reading circuit 17 from the voltage generating circuit 18, to the row select circuit 14 and the column select circuit 15 during reading of data from the memory cell MC.

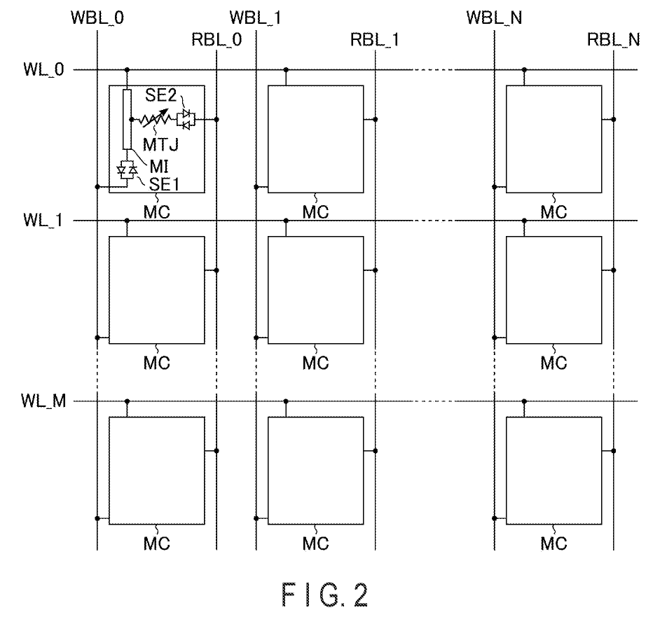

FIG. 2 shows components of the memory cell array 11 of the storage device 1 of the first embodiment and the connections of the components. As shown in FIG. 2, the memory cell array 11 further includes M+1 (M represents a positive integer) word lines WL (WL_0, WL_1, ..., WL_M), N+1 (N represents a positive integer) reading bit lines RBL (RBL_0, RBL_1, ..., RBL_N), and N+1 writing bit lines WBL (WBL_0, WBL_1, ..., WBL_N). One reading bit line RBL and one writing bit line WBL form one pair.

Each memory cell MC is connected to one word line WL and a pair of reading bit line RBL and writing bit line WBL. Each memory cell MC includes a magnetic tunnel junction (MTJ) element MTJ, switching elements SE1 and SE2, and a magnetization wiring MI.

The MTJ element MTJ is an element that exhibits a tunnel magnetoresistance effect, and includes a magnetic tunnel junction (MTJ). The MTJ element is also referred to herein as a “magnetoresistance effect element.” The MTJ element MTJ is a variable resistance element that can be switched between a low-resistance state and a high-resistance state. The MTJ element MTJ can store data of one bit by utilizing the difference between the two resistance states. In one example, the MTJ element MTJ stores “0” data by the low-resistance state and “1” data by the high-resistance state. The following description is based on this example. However, the low-resistance state may instead be associated with “1” data, and the high-resistance state may instead be associated with “0” data.

The switching element SE1 is an element that electrically connects or disconnects both ends of itself. The switching element SE1 has two terminals. When the voltage applied between the two terminals is less than a certain threshold voltage Vth1, the switching element SE1 is in a high-resistance state, and thus it is in an electrically non-conductive state (OFF-state). When the voltage applied between the two terminals is equal to or greater than the threshold voltage Vth1, the switching element SE1 is in a low-resistance state, and thus it is in an electrically conductive state (ON-state). The switching element SE1 has a switching function between the high-resistance state and the low-resistance state based on the magnitude of a voltage applied in a first direction, and the switching element SE1 also has the same switching function in a second direction opposite to the first direction. In other words, the switching element SE1 is a bidirectional switching element. When the voltage between the two terminals becomes equal to or greater than the threshold voltage Vth1 in either case of application of the voltage in the first direction or application of the voltage in the second direction, the switching element SE1 falls into an ON-state. When the voltage between the two terminals becomes less than the threshold voltage Vth1 in either case of the application of the voltage in the first direction or the application of the voltage in the second direction, the switching element SE falls into an OFF-state. The switching element SE1 is connected to one writing bit line WBL at a first end of the switching element SE1.

The switching element SE2 is a bidirectional switching element like the switching element SE1. When the voltage between the two terminals of the switching element SE2 is equal to or greater than a threshold voltage Vth2 in either case of application of the voltage in the first direction or application of the voltage in the second direction, the switching element SE2 falls into an ON-state. When the voltage between the two terminals is less than the threshold voltage Vth2 in either case of application of the voltage in the first direction or application of the voltage in the second direction, the switching element SE2 falls into an OFF-state. The switching element SE2 is connected between a first end of the MTJ element MTJ and one reading bit line RBL.

The magnetization wiring MI is a conductor having magnetization. The magnetization wiring MI includes a first portion, a second portion, and a third portion. The first portion includes a first end of the magnetization wiring MI, and is connected to one word line WL. The second portion includes a second end of the magnetization wiring MI, and is connected to a second end of the switching element SE1. The third portion is a portion between the first portion and the second portion, and is connected to a second end of the MTJ element MTJ. While the switching element SE1 is in the ON-state and the switching element SE2 is in the OFF-state, the magnetization wiring MI functions as a current path between the word line WL and the writing bit line WBL. While the switching element SE1 is in the OFF-state and the switching element SE2 is in the ON-state, a part of the magnetization wiring MI functions as a current path between the word line WL and the reading bit line RBL.

The magnetization wiring MI also generates a force for reversing the direction of magnetization of the memory cell MC during data writing into the memory cell MC.

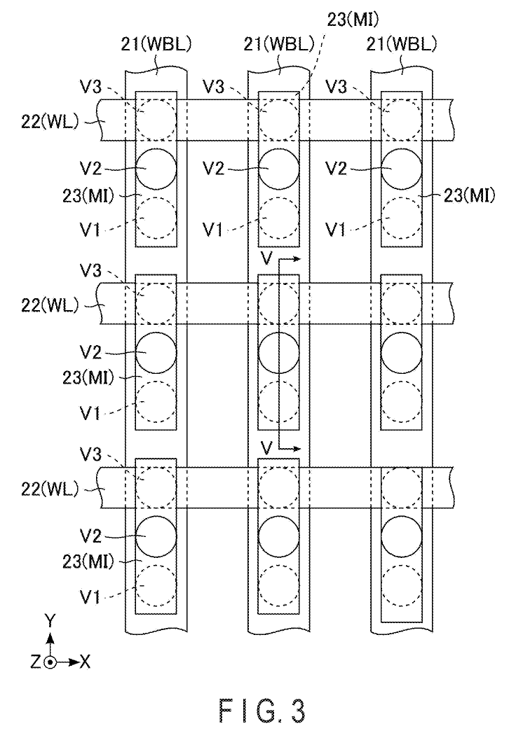

FIG. 3 shows a layout along an X-Y plane of some components of a part of the memory cell array 11 of the storage device 1 of the first embodiment. In FIG. 3 and the following figures and in the following description, a plane along (or parallel to) the surface of a substrate (such as substrate 25 described later) included in the storage device 1 is defined as the X-Y plane. The X-Y plane includes an x-axis and a y-axis that are orthogonal to each other. A direction of the x-axis (toward the right in FIG. 3) is referred to as an X-direction. A direction opposite to the X-direction is referred to as a −X-direction. A direction of the y-axis (upward in FIG. 3) is referred to as a Y-direction. A direction opposite to the Y-direction is referred to as a −Y-direction. A direction that is perpendicular to the X-Y plane and is away from the substrate is referred to as a Z-direction. A direction opposite to the Z-direction is referred to as a −Z direction.

As shown in FIG. 3, the storage device 1 includes conductors 21 and 22, conductors 23, and vertical structures V1, V2, and V3.

The conductors 21 extend in the Y-direction, and are arranged side by side in the X-direction. Each conductor 21 functions as one writing bit line WBL.

The conductors 22 extend in the X-direction, and are arranged side by side in the Y-direction. Each conductor 22 functions as one word line WL. The conductors 22 are located in the Z-direction with respect to the conductors 21.

Each vertical structure V3 overlaps with the conductors 21 and 22. The vertical structures V3 are arranged in a matrix form along the X-Y plane. The vertical structures V3 are located in the Z direction with respect to the conductors 22.

Each vertical structure V1 may be located between two vertical structures V3 aligned in the Y-direction. The vertical structures V1 are arranged in the Y-direction and overlap with the conductors 21. The vertical structures V1 and V3 are arranged alternately one by one in the Y-direction. Each vertical structure V1 includes a structure functioning as one switching element SE1.

Each conductor 23 overlaps with one vertical structure V1 and one vertical structure V3 aligned in the Y-direction. Each conductor 23 functions as one magnetization wiring MI. The conductor 23 is located in the Z-direction with respect to the vertical structures V1 and V3. The conductors 23 each extend in the Y-direction and overlap with one conductor 21. The conductors 23 overlap with the conductors 22.

Each vertical structure V2 overlaps with one conductor 23. Each vertical structure V2 is located between one vertical structure V1 and one vertical structure V3 that overlap with the same conductor 23. In other words, one vertical structure V1, one vertical structure V2, and one vertical structure V3 overlap with one conductor 23, and are arranged side by side in the Y-direction. Each vertical structure V2 is located in the Z-direction with respect to one conductor 23. Each vertical structure V2 includes a structure functioning as one MTJ element MTJ and a structure functioning as one switching element SE2.

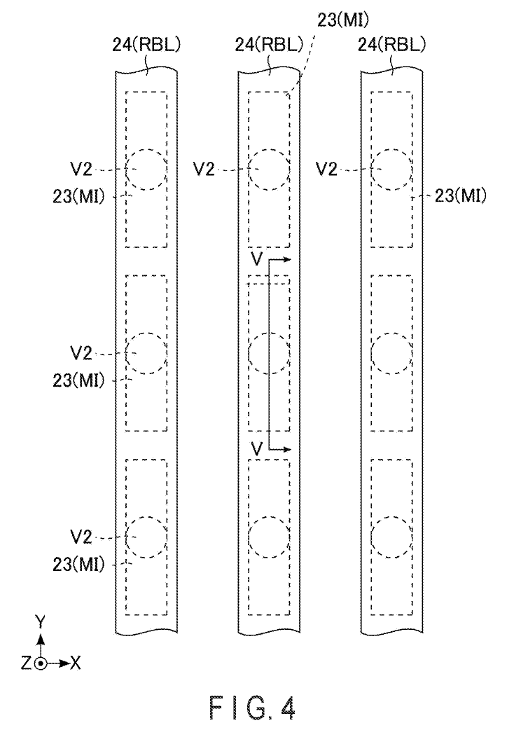

FIG. 4 shows a layout along the X-Y plane of some components of another part of the memory cell array 11 of the storage device 1 of the first embodiment. FIG. 4 shows a region located in the Z-direction with respect to the region shown in FIG. 3 but at the same position along the X-Y plane as the region shown in FIG. 3. As shown in FIG. 4, the storage device 1 further includes conductors 24.

The conductors 24 extend in the Y-direction, and are arranged side by side in the X-direction. Each conductor 24 overlaps with a plurality of conductors 23 arranged side by side in the Y-direction and a plurality of vertical structures V2 arranged side by side in the Y-direction. The conductors 24 are located in the Z-direction with respect to the vertical structures V2.

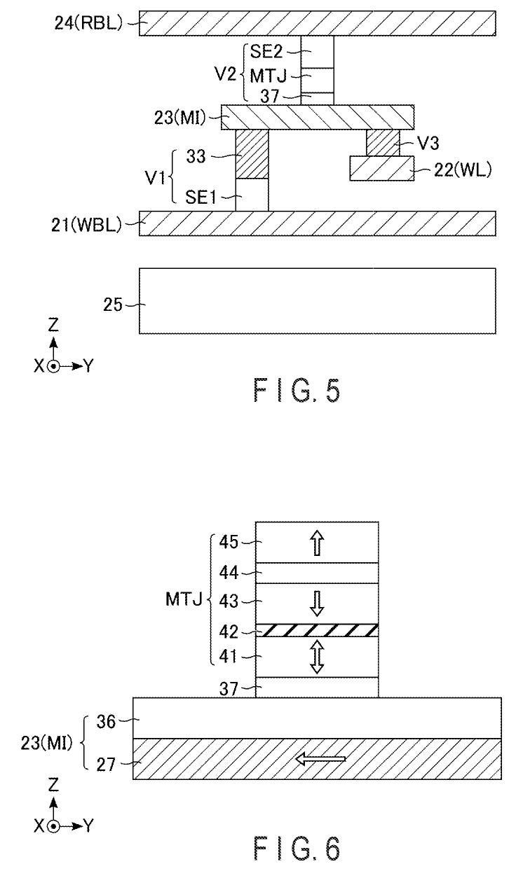

FIG. 5 shows a structure of a part of the storage device 1 of the first embodiment. FIG. 5 shows a structure along a V-V line illustrated in FIGS. 3 and 4, and shows a section taken along a Y-Z plane.

As shown in FIG. 5, the storage device 1 further includes a substrate 25. The substrate 25 extends along the X-Y plane.

The conductors 21 are located in the Z-direction with respect to the substrate 25. Conductors and transistors included in the input/output circuit 12, the control circuit 13, the row select circuit 14, the column select circuit 15, the writing circuit 16, the reading circuit 17, and the voltage generating circuit 18 may be provided between the substrate 25 and the conductors 21.

The vertical structure V1 includes a switching element SE1 and a conductor 33. A -Z-direction side surface (lower surface) of the switching element SE1 is in contact with a Z-direction side surface (upper surface) of the conductor 21. The lower surface of the conductor 33 is in contact with the upper surface of the switching element SE1.

The conductors 22 are located in the Z-direction with respect to the conductors 21. The conductors 22 are spaced apart from the conductors 21. The vertical structure V3 includes a conductor, and the lower surface of the vertical structure V3 is in contact with the upper surface of the conductor 22.

The lower surface of the conductor 23 is in contact with the upper surface of the conductor 33 and the upper surface of the vertical structure V3. The conductors 23 and 33 are thus electrically connected, the switching element SE1 is electrically connected between the conductor 23 and the conductor 21, and the conductors 23 and 21 are electrically connected via the switching element SE1 and the conductor 33.

The vertical structure V2 includes a diffusion prevention layer 37, an MTJ element MTJ, and a switching element SE2. The lower surface of the diffusion prevention layer 37 is in contact with the upper surface of the conductor 23. Details of the diffusion prevention layer 37 will be described later with reference to FIG. 6. The lower surface of the MTJ element MTJ is in contact with the upper surface of the diffusion prevention layer 37. The lower surface of the switching element SE2 is in contact with the MTJ element MTJ.

The lower surface of the conductor 24 is in contact with the upper surface of the switching element SE2. The switching element SE2 is thus electrically connected between the conductor 24 and the MTJ element MTJ, and the MTJ element MTJ is electrically connected between the conductor 24 and the diffusion prevention layer 37.

The structure from the conductor 21 to the conductor 24 in the Z-direction may be repeatedly provided throughout the storage device 1.

FIG. 6 shows the MTJ element MTJ of the storage device 1 of the first embodiment and a surrounding structure thereof.

The MTJ element MTJ includes a ferromagnetic material 41, an insulator 42, a ferromagnetic material 43, a nonmagnetic material 44, and a ferromagnetic material 45.

The ferromagnetic material 41 is a conductor having ferromagnetism, and it may be a ferromagnetic material layer having a layered shape. The ferromagnetic material 41 is located on the upper surface of the diffusion prevention layer 37. The ferromagnetic material 41 has an easy axis of magnetization along the +Z-direction or -Z-direction, in other words, it has perpendicular magnetization. The ferromagnetic material 41 contains iron (Fe). The ferromagnetic material 41 may further contain one or more of cobalt (Co) and nickel (Ni). The ferromagnetic material 41 may further contain boron (B). Specifically, in one example, the ferromagnetic material 41 includes, or substantially consists of, cobalt iron boron or iron boride. As used herein, a component “substantially consisting of” or being “substantially composed of” a material may contain unintentional impurities besides that material. The direction of magnetization of the ferromagnetic material 41 can be changed by data writing into the memory cell MC, and the ferromagnetic material 41 then functions as a storage layer. Hereinafter, the ferromagnetic material 41 is also referred to as a “storage layer SL.”

The ferromagnetic material 41 may include a laminated film of a layer A and a layer B. The layer A is a layer containing one or more of cobalt, iron, and nickel. The layer B is a layer containing one or more of platinum (Pt), iridium (Ir), palladium (Pd), and gold (Au). Examples of the laminated film include a laminated film of cobalt and platinum, a laminated film of cobalt and iridium, and a laminated film of cobalt and palladium. A layer containing cobalt iron boron may be further stacked on the laminated film, the layer containing cobalt iron boron thus being located between the ferromagnetic material 41 and the insulator 42.

The insulator 42 is a nonmagnetic insulator, and it may be an insulator layer having a layered shape. In one example, the insulator 42 contains magnesium oxide (MgO), in some cases substantially consisting of magnesium oxide, and functions as a tunnel barrier. In some embodiments, magnetic properties can be measured or identified by magnetic permeability, magnetic susceptibility, or coercivity. In some embodiments, the insulator 42 has a lower value for a magnetic property (e.g., lower magnetic permeability, magnetic susceptibility, or coercivity) than the ferromagnetic material 41 and/or the ferromagnetic material 43 have.

The ferromagnetic material 43 is a conductor having ferromagnetism, and it may be a ferromagnetic material layer having a layered shape. The ferromagnetic material 43 has an easy axis of magnetization along the -Z-direction, in other words, it has perpendicular magnetization. In one example, the ferromagnetic material 43 contains one or more of cobalt platinum (CoPt), cobalt nickel (CoNi), and cobalt palladium (CoPd), in some cases substantially consisting of cobalt platinum, cobalt nickel, or cobalt palladium. The direction of magnetization of the ferromagnetic material 43 is unchanged for data reading from and data writing into the memory cell MC, i.e., not switchable. The ferromagnetic material 43 functions as a reference layer. Hereinafter, the ferromagnetic material 43 is also referred to as a “reference layer RL”.

The nonmagnetic material 44 is a conductor having a nonmagnetic property, and it may be a nonmagnetic material layer having a layered shape. In some embodiments, the nonmagnetic material 44 has a lower value for a magnetic property (e.g., lower magnetic permeability, magnetic susceptibility, or coercivity) than the ferromagnetic material 43 or the ferromagnetic material 45 have. The nonmagnetic material 44 functions as a spacer layer. In one example, the nonmagnetic material 44 contains one or more of ruthenium (Ru), osmium (Os), rhodium (Rh), iridium (Ir), vanadium (V), and chromium (Cr), in some cases substantially consisting of ruthenium, osmium, rhodium, iridium, vanadium, or chromium. The nonmagnetic material 44 antiferromagnetically couples the ferromagnetic material 43 and the ferromagnetic material 45. The nonmagnetic material 44 has a thickness of 2 nm or less.

The ferromagnetic material 45 is a conductor having ferromagnetism, and it may be a ferromagnetic material layer having a layered shape. The ferromagnetic material 45 functions as a shift cancelling layer. The ferromagnetic material 45 has an easy axis of magnetization along the +Z-direction, in other words, it has perpendicular magnetization. In one example, the ferromagnetic material 45 contains one or more of cobalt platinum, cobalt nickel, and cobalt palladium, in some cases substantially consisting of cobalt platinum, cobalt nickel, or cobalt palladium. The ferromagnetic material 45 is antiferromagnetically coupled to the ferromagnetic material 43 by the nonmagnetic material 44. In other words, the ferromagnetic material 43 and the ferromagnetic material 45 are coupled to each other so as to have antiparallel magnetization directions. Such a structure consisting of the ferromagnetic material 43, the nonmagnetic material 44, and the ferromagnetic material 45 can restrain the influence of a leakage magnetic field of the ferromagnetic material 43 on the magnetization direction of the ferromagnetic material 41. In some cases, the nonmagnetic material 44 and the ferromagnetic material 45 may be omitted.

The conductor 23 (magnetization wiring MI) includes a ferromagnetic material 27 and a nonmagnetic intermediate layer 36. In some embodiments, the nonmagnetic intermediate layer 36 has a lower value for a magnetic property (e.g., lower magnetic permeability, magnetic susceptibility, or coercivity) than the ferromagnetic material 27 has. The ferromagnetic material 27 is a conductor having ferromagnetism, and it may be a ferromagnetic material layer having a layered shape. In one example, the ferromagnetic material 27 includes at least one element selected from iron (Fe) and cobalt (Co). In one example, the ferromagnetic material 27 contains cobalt iron boron (CoFeB), in some cases substantially consisting of cobalt iron boron. The ferromagnetic material 27 may contain nickel (Ni). The ferromagnetic material 27 has in-plane magnetization. In other words, the ferromagnetic material 27 has an easy axis of magnetization along the X-Y plane. Furthermore, the ferromagnetic material 27 may have magnetization oriented in the -Y-direction. The following description is based on this example. However, the ferromagnetic material 27 may instead have magnetization oriented in the +Y-direction.

Heavy metal elements such as Pt, Ti, and Ta are not purposefully included in the ferromagnetic material 27, so the ferromagnetic material 27 may contain none of these heavy metal elements, i.e., the ferromagnetic material 27 may lack all of these heavy metal elements. However, negligible amounts of such elements may be present as unintentional byproducts of a manufacturing process, e.g., of the ferromagnetic material 27 or the storage device 1. Any inclusion of such elements is expected to be limited to trace levels that are inconsequential to the operation or composition of the ferromagnetic material 27.

The nonmagnetic intermediate layer 36 is a layer of a nonmagnetic metal. The lower surface of the nonmagnetic intermediate layer 36 is in contact with the upper surface of the ferromagnetic material 27. In one example, the nonmagnetic intermediate layer 36 contains a light metal element, in some cases substantially consisting of a light metal element. Examples of the light metal element include titanium (Ti), magnesium (Mg), and aluminum (Al). The nonmagnetic intermediate layer 36 cooperates with the ferromagnetic material 27 to generate a force for reversing the magnetization of the ferromagnetic material 41. Such a force is considered to be based on the same or similar mechanism as the reversal of the magnetization of the ferromagnetic material caused by spin orbit torque (SOT). In other words, a spin orbit torque is generated in the nonmagnetic intermediate layer 36 based on the current flowing through the ferromagnetic material 27, and the generated spin orbit torque enters the ferromagnetic material 41 to reverse the magnetization direction of the ferromagnetic material 41. However, as mentioned earlier, the magnetization direction of the ferromagnetic material 43 is not switchable by the spin orbit torque. Hereinafter, the force that is generated in the nonmagnetic intermediate layer 36 based on the current flowing through the ferromagnetic material 27 and that reverses the magnetization of the ferromagnetic material 41, is referred to as “spin orbit torque.”

The lower surface of the diffusion prevention layer 37 is in contact with the upper surface of the nonmagnetic intermediate layer 36. In some embodiments, the diffusion prevention layer 37 has a lower value for a magnetic property (e.g., lower magnetic permeability, magnetic susceptibility, or coercivity) than the ferromagnetic material 27 has. The upper surface of the diffusion prevention layer 37 is in contact with the lower surface of the ferromagnetic material 41.

The diffusion prevention layer 37 includes a material that prevents elements in the diffusion prevention layer 37 and/or the nonmagnetic intermediate layer 36 from diffusing into the ferromagnetic material 41 even when the storage device 1 is heated during a manufacturing process of the storage device 1. Furthermore, the diffusion prevention layer 37 has a material and a thickness that allow the spin orbit torque occurring in the nonmagnetic intermediate layer 36 to pass through the diffusion prevention layer 37 and reach the ferromagnetic material 41. The diffusion prevention layer 37 includes a material that prevents elements contained in the nonmagnetic intermediate layer 36 from diffusing into the ferromagnetic material 41 and also prevents elements contained in the ferromagnetic material 41 from diffusing into the nonmagnetic intermediate layer 36. In one example, the diffusion prevention layer 37 has a thickness of 1 nm or less. In one example, the diffusion prevention layer 37 contains a heavy metal element having a small solid solubility limit. Examples of the heavy metal element include tungsten (W), tantalum, molybdenum (Mo), hafnium (Hf), and rare earth metals. For example, the surface of the diffusion prevention layer 37 may be oxidized, whereby the diffusion prevention function can be enhanced. As another example, instead of or in addition to such heavy metal element, the diffusion prevention layer 37 may contain one or more of: (1) a material comprising titanium and oxygen (O), such as titanium oxide (TiO), (2) a material comprising titanium and nitrogen (N), such as titanium nitride (TiN), (3) a material comprising magnesium and oxygen, such as magnesium oxide, (4) a material comprising magnesium and nitrogen, such as magnesium nitride (MgN), (5) a material comprising aluminum and oxygen, such as aluminum oxide, (6) a material comprising aluminum and nitrogen, such as aluminum nitride, (7) a material comprising nickel and oxygen, such as nickel oxide, or (8) a material comprising nickel and nitrogen, such as nickel nitride. In some cases, the diffusion prevention layer 37 may substantially consist of titanium oxide, titanium nitride, magnesium oxide, magnesium nitride, aluminum oxide, aluminum nitride, nickel oxide, or nickel nitride.

When the magnetization direction of the storage layer SL is parallel to the magnetization direction of the reference layer RL, the MTJ element MTJ has a low resistance. The state in which the magnetization direction of the storage layer SL is parallel to the magnetization direction of the reference layer RL is referred to herein as a “parallel state.”

When the magnetization direction of the storage layer SL is antiparallel to the magnetization direction of the reference layer RL, the MTJ element MTJ has a resistance higher than the resistance thereof when the magnetization directions of the storage layer SL and the reference layer RL are parallel to each other. The state in which the magnetization direction of the storage layer SL is antiparallel to the magnetization direction of the reference layer RL is referred to herein as an “antiparallel state.”

Data reading is performed by causing current to flow between the reading bit line RBL and the word line WL while the switching element SE1 is in the OFF-state and the switching element SE2 is in the ON-state. Based on the terminal voltage of the MTJ element MTJ which is caused by the flow of current, it is identified which one of a parallel state (low-resistance state) and an anti-parallel state (high-resistance state) the MTJ element MTJ is set in.

The magnetization direction of the storage layer SL is changed by the spin orbit torque. The spin orbit torque is generated by passing current through the conductor 23. A writing current, referred to herein as “Ic0,” having a certain threshold magnitude or greater, is passed through the conductor 23 (the ferromagnetic material 27 and the nonmagnetic intermediate layer 36) in a direction (+Y-direction) along the magnetization direction of the conductor 23, whereby the magnetization direction of the storage layer SL and the magnetization direction of the reference layer RL are parallel to each other. On the other hand, a writing current, referred to herein as “Ic1,” having a certain threshold magnitude or greater, is passed through the conductor 23 in the opposite direction (-Y-direction) to the magnetization direction of the conductor 23, whereby the magnetization direction of the storage layer SL and the magnetization direction of the reference layer RL are antiparallel to each other. The writing current Ic1 is larger than the writing current Ic0.

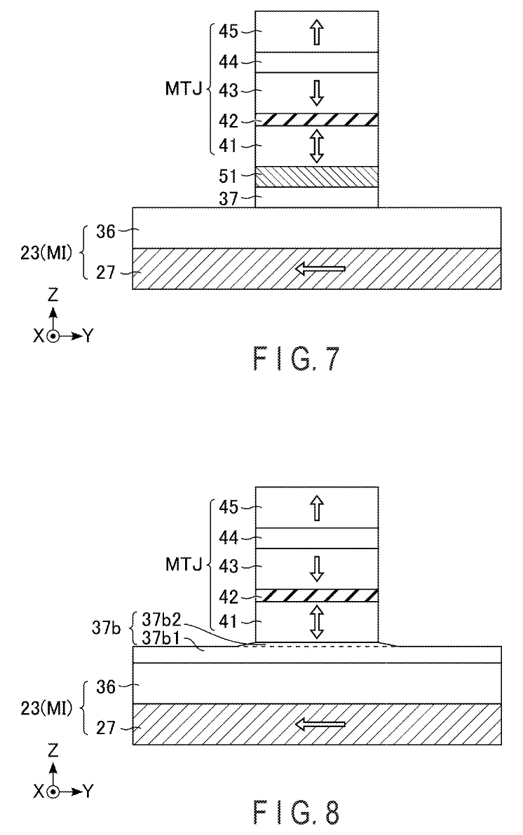

The vertical structure V2 may include an additional layer. In one example, the vertical structure V2 may include a ferromagnetic material 51 between the diffusion prevention layer 37 and the ferromagnetic material 41 as shown in FIG. 7. The ferromagnetic material 51 is a conductor having ferromagnetism, and it may be a ferromagnetic material layer having a layered shape. In one example, the ferromagnetic material 51 contains one or more of iron, cobalt, nickel, and gadolinium. In one example, the ferromagnetic material 51 may contain a heavy metal. Examples of the heavy metal include platinum, titanium, and tantalum. In some embodiments, the ferromagnetic material 51 has a higher value for a magnetic property (e.g., higher magnetic permeability, magnetic susceptibility, or coercivity) than the diffusion prevention layer 37 has.

According to the first embodiment, as described below, a storage device is provided that can write data without any need for magnetic field assistance, and that has stable magnetization.

A storage device of a first comparative example includes a conductor layer for applying a bias magnetic field, and further includes a wiring, sometimes referred to as an “SOT wiring.” In the storage device of the first comparative example, a ferromagnetic material that functions as the storage layer has perpendicular magnetization. The magnetization direction of the storage layer can be reversed by a spin orbit torque generated by a current flowing through the SOT wiring, with the assistance of the bias magnetic field generated by a current flowing through the conductor layer.

The storage device 1 has a simpler structure than the first comparative example because a bias magnetic field is not required to reverse the magnetization direction of the ferromagnetic material 41. Furthermore, whereas the SOT wiring of the first comparative example often contains heavy metal, the ferromagnetic material 27 is required only to contain materials similar to the ferromagnetic material 41 such as iron, cobalt, nickel, and boron, and does not need to contain heavy metal. Therefore, from this point of view as well, the structure of the storage device 1 is simpler than the first comparative example.

According to a second comparative example, the magnetization direction of the ferromagnetic material 41 can be reversed by a stacked structure of the ferromagnetic material 27 having in-plane magnetization, the nonmagnetic intermediate layer 36, and the ferromagnetic material 41, as included in the storage device 1 of the first embodiment. The reversal of the magnetization direction by such a structure does not require the application of a bias magnetic field for reversal of magnetization direction using a reference spin orbit torque. Instead, in a structure of the second comparative example, for reversal of the magnetization direction using a reference spin orbit torque (hereinafter, sometimes referred to as a “reference structure”), an SOT wiring is included below the MTJ element MTJ. This SOT wiring functions as a current path (similar to the ferromagnetic material 27 of the storage device 1), and this SOT wiring is configured to generate a leakage magnetic field to be applied to the interface with the storage layer. The leakage magnetic field and the spin orbit torque generated by the current flowing through the SOT wiring cooperate with each other to reverse the magnetization direction of the storage layer.

It should be noted that if the nonmagnetic intermediate layer 36 and the ferromagnetic material 41 were instead in contact with each other, the elements in one layer would likely diffuse into the other layer. In particular, when cobalt in the ferromagnetic material 41 would diffuse out of the ferromagnetic material 41, the perpendicular magnetization of the ferromagnetic material 41 would disappear. Generally, it would be necessary to apply heat of about 400°C to the ferromagnetic material 41 to strengthen the perpendicular magnetization, whereas diffusion would occur at about 200°C. As a result, the perpendicular magnetization of the ferromagnetic material 41 would not be able to be maintained. Also, the heat resistance of about 200°C is insufficient for a storage device.

According to the first embodiment, the diffusion prevention layer 37 is provided between the nonmagnetic intermediate layer 36 and the ferromagnetic material 41. This prevents an element contained in one of the ferromagnetic material 41 and the nonmagnetic intermediate layer 36 from diffusing into the other. Therefore, it is possible to maintain the perpendicular magnetization of the ferromagnetic material 41. Furthermore, it is possible to reverse the magnetization direction with a simpler structure than the reference structure of the second comparative example.

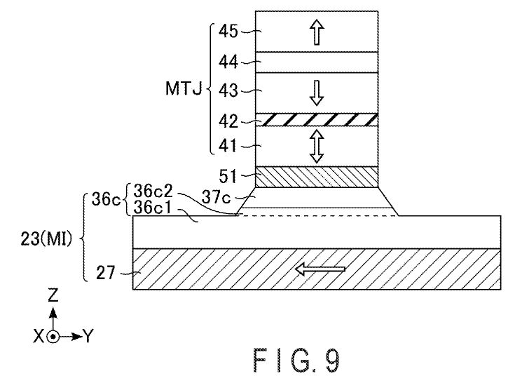

The MTJ element MTJ of the storage device 1 and its surrounding components may also have structures shown in FIG. 8 and FIG. 9. FIG. 8 and FIG. 9 show the MTJ element MTJ of a storage device 1 of other modifications of the first embodiment, and its surrounding structure.

As shown in FIG. 8, a diffusion prevention layer 37b has a first portion 37b1 and a second portion 37b2. The first portion 37b1 occupies a region including a lowermost part of the diffusion prevention layer 37b. The first portion 37b1 extends along the Y-axis, and in one example, has a shape that matches the shape of the conductor 23.

The second portion 37b2 occupies a region including an uppermost part of the diffusion prevention layer 37b. The lower surface of the second portion 37b2 is connected to the upper surface of the first portion 37b1. The side surface of the second portion 37b2 has an inverted tapered shape that narrows in the +Z direction. In other words, the length of the second portion 37b2 along the Y-direction increases as the second portion 37b2 extends toward the -Z-direction. In one example, the second portion 37b2 has a truncated cone shape. The shape of the upper surface of the second portion 37b2 matches the shape of the lower surface of the ferromagnetic material 41.

As shown in FIG. 9, the side surface of a diffusion prevention layer 37c has an inverted tapered shape that narrows in the +Z direction. In one example, the diffusion prevention layer 37c has a truncated cone shape.

The nonmagnetic intermediate layer 36c has a first portion 36c1 and a second portion 36c2. The first portion 36c1 occupies a region including a lowermost part of the nonmagnetic intermediate layer 36c. The first portion 36c1 extends along the Y-axis and, in one example, it has a shape that matches the shape of the ferromagnetic material 27.

The second portion 36c2 occupies a region including an uppermost part of the nonmagnetic intermediate layer 36c. The lower surface of the second portion 36c2 is connected to the upper surface of the first portion 36c1. The side surface of the second portion 36c2 has an inverted tapered shape that narrows in the +Z direction. In one example, the second portion 36c2 has a truncated cone shape. The shape of the upper surface of the second portion 36c2 matches the shape of the lower surface of the diffusion prevention layer 37c.

The above advantages can also be obtained by the structures shown in FIGS. 8 and 9.

While certain embodiments have been described, these embodiments have been presented by way of example only, and are not intended to limit the scope of the invention. Indeed, the novel devices and methods described herein may be embodied in a variety of other forms; furthermore, various omissions, substitutions and changes in the form of the embodiments described herein may be made without departing from the spirit of the invention. The accompanying claims and their equivalents are intended to cover such forms or modifications as would fall within the scope and spirit of the invention.

What is claimed is:

1. A storage device comprising:
a first conductor;
a first material that extends in a first direction, that is located in a second direction with respect to the first conductor, and that is electrically connected to the first conductor, wherein the second direction intersects the first direction;
a second conductor electrically connected to the first material;
a second material that is located in the second direction with respect to the first material, that is in contact with the first material, and that contains one or more of titanium, magnesium, and aluminum;
a third material that is located in the second direction with respect to the second material, that is in contact with the second material, and that contains (1) a metal selected from tungsten, tantalum, molybdenum, hafnium, and rare earth metals, (2) a material comprising titanium and oxygen, (3) a material comprising titanium and nitrogen, (4) a material comprising magnesium and oxygen, (5) a material comprising magnesium and nitrogen, (6) a material comprising aluminum and oxygen, (7) a material comprising aluminum and nitrogen, (8) a material comprising nickel and oxygen, or (9) a material comprising nickel and nitrogen;
a magnetoresistance effect element that is located in the second direction with respect to the third material and that is connected to the third material; and
a third conductor located in the second direction with respect to the magnetoresistance effect element, wherein
the magnetoresistance effect element is electrically connected between the third conductor and the third material, and
the second material and the third material have a lower value for a magnetic property than the first material has.

2. The storage device of claim 1, wherein the first material contains iron or cobalt.

3. The storage device of claim 2, wherein the first material further contains boron.

4. The storage device of claim 1, wherein the first material lacks platinum, titanium, and tantalum.

5. The storage device of claim 1,
wherein the magnetoresistance effect element includes:
a fourth material that is located in the second direction with respect to the third material and that is connected to the third material,
a fifth material located in the second direction with respect to the fourth material, and
a sixth material located between the fourth material and the fifth material, and
wherein the sixth material has lower value for the magnetic property than the fourth material and the fifth material have.

6. The storage device of claim 5, wherein the fourth material contains iron or cobalt.

7. The storage device of claim 6, wherein the fourth material further contains boron.

8. The storage device of claim 5, wherein the fifth material contains cobalt platinum, cobalt nickel, or cobalt palladium.

9. The storage device of claim 5, wherein
a magnetization direction of the fourth material is changed according to a first current flowing through the first material between the first conductor and the second conductor, and
a magnetization direction of the fifth material is unchanged by the first current.

10. The storage device of claim 9, wherein
the fourth material has an easy axis of magnetization along either the second direction or a direction opposite to the second direction, and
the fifth material has an easy axis of magnetization along the direction opposite to the second direction.

11. The storage device of claim 5,
wherein the magnetoresistance effect element further includes:
a seventh material located in the second direction with respect to the fifth material, and
an eighth material located between the fifth material and the seventh material, and
wherein the eighth material has lower value for the magnetic property than the seventh material has.

12. The storage device of claim 11, wherein the seventh material has an easy axis of magnetization along the second direction.

13. The storage device of claim 5, further comprising:
a seventh material located between the third material and the fourth material, wherein the seventh material has higher value for the magnetic property than the third material has.

14. The storage device of claim 1, wherein the third material has a thickness of 1 nm or less.

15. The storage device of claim 1, further comprising:
a first switching element located between the first conductor and the first material, wherein the first switching element is electrically connected between the first conductor and the first material.

16. The storage device of claim 15, further comprising:
a second switching element located between the magnetoresistance effect element and the third conductor, wherein the second switching element is electrically connected between the magnetoresistance effect element and the third conductor.

17. The storage device of claim 1, wherein the first material has an easy axis of magnetization along the first direction.

18. The storage device of claim 1, wherein the third material includes a first portion and a second portion, the second portion being located in the second direction with respect to the first portion, and a side surface of the second portion having an inverted tapered shape that narrows in the second direction.

19. The storage device of claim 1, wherein the second material includes a first portion and a second portion, the second portion being located in the second direction with respect to the first portion, and a side surface of the second portion having an inverted tapered shape that narrows in the second direction.

20. The storage device of claim 19, wherein a side surface of the third material has an inverted tapered shape that narrows in the second direction.
